(19) United States
(12) Patent Application Publication
(10) Pub. No.: US 2022/0271064 A1
(43) Pub. Date: Aug. 25, 2022

(54) Driving Backplane, Preparation Method for Same, and Display Device

(71) Applicants: Hefei Xinsheng Optoelectronics Technology Co., Ltd., Hefei (CN); BOE Technology Group Co., Ltd., Beijing (CN)

(72) Inventors: Ting ZENG, Beijing (CN); Yu JIANG, Beijing (CN); Yongfei LI, Beijing (CN); Huan LIU, Beijing (CN); Zhongzheng YANG, Beijing (CN)

(21) Appl. No.: 17/511,581

(22) Filed: Oct. 27, 2021

(30) Foreign Application Priority Data
Feb. 24, 2021 (CN) 202110209189.5

(51) Int. Cl. H01L 27/12

(52) U.S. Cl. CPC H01L 27/1244; H01L 27/1288

(57) ABSTRACT

Provided are a driving backplane, a preparation method for the same, and a display device. The driving backplane includes a driving structure layer arranged on a base and a supporting structure arranged on a side of the driving structure layer away from the base. The driving structure layer includes a first conductive layer and a second conductive layer which are stacked. There is no overlapping region between an orthographic projection of the supporting structure on the base and an orthographic projection of at least one of the first conductive layer and the second conductive layer on the base.

### CROSS-REFERENCE TO RELATED APPLICATION

The present application claims priority to Chinese patent application No. 202110209189.5, filed to the CNIPA on Feb. 24, 2021, the contents of which are hereby incorporated by reference.

### TECHNICAL FIELD

Embodiments of the present disclosure relate, but are not limited, to the technical field of display, and particularly to a driving backplane, a preparation method for the same, and a display device.

### BACKGROUND

Semiconductor Light Emitting Diode (LED) technologies have been developed for nearly thirty years from initial solid-state lighting power supplies to backlight sources in the field of display and then to LED display screens, which lays a solid foundation for more extensive applications thereof. With the development of chip fabrication and encapsulation technologies, backlight sources adopting submillimeter-level and even micron-level micro LEDs have been applied extensively.

A main body structure of an LED-technology-based backlight source includes a driving backplane and a control circuit. Light emitting diodes on the driving backplane may be accurately adjusted by the control circuit to implement High Dynamic Range (HDR) display.

At present, the preparation of driving backplanes has a more serious short-circuit problem, and has a lower yield.

### SUMMARY

The below is a summary about the subject matter described in the present disclosure in detail. The summary is not intended to limit the scope of protection of the claims.

An embodiment of the present disclosure provides a driving backplane, which includes a driving structure layer arranged on a base and a supporting structure arranged on a side of the driving structure layer away from the base. The driving structure layer includes a first conductive layer and a second conductive layer which are stacked. There is no overlapping region between an orthographic projection of the supporting structure on the base and an orthographic projection of at least one of the first conductive layer and the second conductive layer on the base.

In an exemplary implementation, the supporting structure includes any one or more of a supporting column and a supporting dam.

In an exemplary implementation, a distance between a surface of a side of the supporting structure away from the base and a surface of the side of the driving structure layer away from the base is 10 μm to 50 μm.

In an exemplary implementation, the driving structure layer includes a first insulating layer arranged on the base, the first conductive layer arranged on a side of the first insulating layer away from the base, a second insulating layer and a third insulating layer which cover the first conductive layer, the second conductive layer arranged on a side of the third insulating layer away from the base, a fourth insulating layer covering the second conductive layer, and a fifth insulating layer arranged on a side of the fourth insulating layer away from the base. The supporting structure is arranged on a side of the fifth insulating layer away from the base.

In an exemplary implementation, the fifth insulating layer is made of the same material as the supporting structure.

In an exemplary implementation, a pattern of the supporting structure is complementary to that of the first conductive layer, or, a pattern of the supporting structure is complementary to that of the second conductive layer.

An embodiment of the present disclosure further provides a display device, which includes any above-mentioned driving backplane.

An embodiment of the present disclosure also provides a preparation method for a driving backplane, which includes the following operations.

A driving structure layer is formed on a base. Herein, the driving structure layer includes a first conductive layer and a second conductive layer which are stacked.

A supporting structure is formed on the driving structure layer. Herein, there is no overlapping region between an orthographic projection of the supporting structure on the base and an orthographic projection of at least one of the first conductive layer and the second conductive layer on the base.

In an exemplary implementation, the operation that a driving structure layer is formed on a base includes the following operations.

A first insulating layer and the first conductive layer arranged on the first insulating layer are formed on the base.

A second insulating layer and a third insulating layer which cover the first conductive layer are formed.

The second conductive layer is formed on the third insulating layer.

A fourth insulating layer covering the second conductive layer is formed.

A fifth insulating layer is formed on the fourth insulating layer.

In an exemplary implementation, the operation that a fifth insulating layer is formed on the fourth insulating layer includes that: the fourth insulating layer is coated with a fifth insulating thin film, and the fifth insulating layer is formed by a patterning process based on a first ordinary mask; the operation that a supporting structure is formed on the driving structure layer includes that: the fifth insulating layer is coated with a supporting thin film, and the supporting structure is formed by a patterning process based on a second ordinary mask.

In an exemplary implementation, the second ordinary mask is the same as a mask for forming the first conductive layer to enable a pattern of the supporting structure to be complementary to that of the first conductive layer. Or, the second ordinary mask is the same as a mask for forming the second conductive layer to enable a pattern of the supporting structure to be complementary to that of the second conductive layer.

In an exemplary implementation, the formation of the fifth insulating layer on the fourth insulating layer and the formation of the supporting structure on the driving structure layer are implemented by a patterning process based on a gray tone mask.

In an exemplary implementation, a distance between a surface of a side of the supporting structure away from the base and a surface of a side of the driving structure layer away from the base is 10 μm to 50 μm.

Other aspects will become apparent upon reading and understanding the drawings and the detailed description.

### BRIEF DESCRIPTION OF DRAWINGS

The drawings, which constitute a part of the specification, are used to provide an understanding to the technical solution of the present disclosure and explain, together with the embodiments of the present disclosure, the technical solutions of the present disclosure and not intended to form limits to the technical solutions of the present disclosure.

FIG. 1 is a schematic diagram of a structure of a driving backplane.

FIG. 2 is a planar schematic diagram of a structure of an emitting unit in a driving backplane.

FIG. 3 is an enlarged view of a circuit pad in FIG. 2.

FIG. 4 is a schematic diagram of a sectional structure of an emitting unit in a driving backplane according to an exemplary embodiment of the present disclosure.

FIG. 5 is a schematic diagram of a driving backplane after a pattern of a first conductive layer is formed according to an exemplary embodiment of the present disclosure.

FIG. 6 is a sectional view along direction A-A in FIG. 5.

FIG. 7 is a schematic diagram of a driving backplane after a pattern of a third insulating layer is formed according to an exemplary embodiment of the present disclosure.

FIG. 8 is a sectional view along direction A-A in FIG. 7.

FIG. 9 is a schematic diagram of a driving backplane after a pattern of a second conductive layer is formed according to an exemplary embodiment of the present disclosure.

FIG. 10 is a sectional view along direction A-A in FIG. 9.

FIG. 11 is a schematic diagram of a driving backplane after a pattern of a supporting structure is formed according to an exemplary embodiment of the present disclosure.

FIG. 12 is a sectional view along direction A-A in FIG. 11.

FIG. 13 is an enlarged view of a pad region in FIG. 11.

FIGS. 14a and 14b are schematic diagrams of structures of a supporting column according to an exemplary embodiment of the present disclosure.

FIGS. 15a and 15b are schematic diagrams of structures of a supporting dam according to an exemplary embodiment of the present disclosure.

FIG. 16 is a planar schematic diagram of a structure of a bonding region in a driving backplane according to an exemplary embodiment of the present disclosure.

FIGS. 17a, 17b and 17c are schematic diagrams of sharing mask according to an exemplary embodiment of the present disclosure.

### DETAILED DESCRIPTION

The embodiments of the present disclosure will be described below in combination with the drawings in detail. It is to be noted that implementations may be implemented in various forms. Those of ordinary skill in the art may easily understand such a fact that manners and contents may be transformed into various forms without departing from the purpose and scope of the present disclosure. Therefore, the present disclosure should not be explained as being limited to the contents recorded in the following implementations only. The embodiments in the present disclosure and the features in the embodiments may be freely combined without conflicts.

In the drawings, the sizes of composition elements, the thicknesses of layers, or regions are exaggerated sometimes for clarity. Therefore, an implementation of the present disclosure is not always limited to the size, and the shapes and sizes of each component in the drawings do not reflect the true scale. In addition, the drawings schematically illustrate ideal examples, and an implementation of the present disclosure is not limited to the shapes, numerical values, or the like shown in the drawings.

Ordinal numerals “first”, “second”, “third”, etc., in the present specification are set to avoid the confusion of composition elements, rather than limitations in number.

In the present specification, for convenience, wordings such as “central”, “upper”, “lower”, “front”, “rear”, “vertical”, “horizontal”, “top”, “bottom”, “inner”, “outer” and the others describing orientations or positional relations are used to depict positional relations of constituent elements with reference to the drawings, which are only for convenience of describing the specification and simplifying the description, rather than indicating or implying that the device or element referred to must have a specific orientation, or must be constructed and operated in a particular orientation, and therefore, those wordings cannot be construed as limitations on the present disclosure. The positional relations of the constituent elements may be appropriately changed according to a direction in which constituent elements are described. Therefore, the wordings are not limited in the specification, and may be replaced appropriately according to situations.

In the present specification, unless otherwise specified and defined, terms “mounting”, “mutual connection”, and “connection” should be in their broadest sense understood. For example, a connection may be a fixed connection, or detachable connection, or integral connection. It may be a mechanical connection or electric connection. It may be a direct connection, or indirect connection through an intermediate, or communication inside two elements. Those of ordinary skill in the art may understand the meanings of the terms in the present disclosure according to specific situations.

In the present specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current may flow through the drain electrode, the channel region, and the source region. It is to be noted that, in the present specification, the channel region refers to a region that the current mainly flows through.

In the present specification, the first electrode may be the drain electrode, and the second electrode may be the source electrode. Alternatively, the first electrode may be the source electrode, and the second electrode may be the drain electrode. In cases that transistors with opposite polarities are used, or a current direction changes during work of a circuit, or the like, functions of the “source electrode” and the “drain electrode” may sometimes be exchanged. Therefore, the “source electrode” and the “drain electrode” may be exchanged in the present specification.

In the present specification, “an electrical connection” includes connection of composition elements through an element with a certain electrical action. “The element with the certain electrical action” is not particularly limited as long as it may send and receive electrical signals between the connected composition elements. Examples of “the element with the certain electrical action” not only include an electrode and wiring, but also include a switch element such as a transistor, a resistor, an inductor, a capacitor, other elements with multiple functions, etc.

In the present specification, “parallel” refers to a state that an angle formed by two straight lines is above −10° and below 10°, and thus may include a state that the angle is above −5° and below 5°. In addition, “perpendicular” refers to a state that an angle formed by two straight lines is above 80° and below 100°, and thus may include a state that the angle is above 85° and below 95°.

In the present specification, “film” and “layer” may be exchanged. For example, “conductive layer” may be replaced with “conductive film” sometimes. Similarly, “insulating film” may be replaced with “insulating layer” sometimes.

In the present disclosure, “about” refers to situations where limits are not strictly defined and numerical values in process and measurement error ranges are allowed.

Micro LEDs may include Micro Light Emitting Diodes (LEDs) and Mini Light Emitting Diodes (LEDs), have the advantages of small size, high brightness, etc., and may be applied to backlight modules of display devices extensively. A picture contrast of a display product using a micro LED backlight source may achieve a level of an Organic Light-Emitting Diode (OLED) display product. The product may keep the technical advantages of Liquid Crystal Display (LCD) to further improve the picture display effect and provide better visual experiences for users. In addition, the micro LED display gradually becomes a hot spot of the display panel and is mainly applied to the fields of Augmented Reality (AR)/Virtual Reality (VR), Televisions (TVs), outdoor display, etc.

For present micro LED backlight sources, miniaturization, arraying and thin film formation processes are usually performed on LED chips by a miniaturization processing technology, and the LED chips are transferred in batches to driving backplanes by a mass transfer technology. A typical size (e.g., length) of a Micro LED may be less than 50 μm, e.g., 10 μm to 50 μm. A typical size (e.g., length) of a Mini LED may be about 50 μm to 150 μm, e.g., 80 μm to 120 μm. A driving backplane usually includes multiple emitting units. Each emitting unit may include multiple micro LEDs connected in series and a Display Drive Integrated Circuit (DDIC) connected with a control circuit. At present, a driving backplane preparation process has a relatively serious short-circuit problem which is partially caused by particles generated in the driving backplane preparation process. At present, particles may be generated during preparation processes of multiple structural film layers of the driving backplane, which cannot be completely avoided. Since a region with the particles is higher than a region around, squeezing on the driving backplane in subsequent screen printing and soldering processes may cause damage of a film layer in the region with the particles. When a position at which the film layer is damaged is right in an overlapping region of two conductive layers, the two conductive layers may be turned on to cause Data Gate Short (DGS), the main phenomenon of which is a cross bright line. In addition, even though the film layer damage does not turn on the two conductive layers, water vapor easily enters from the position at which the film layer is damaged to corrode the conductive layers, so there are still risks of defects such as, short-circuit, etc.

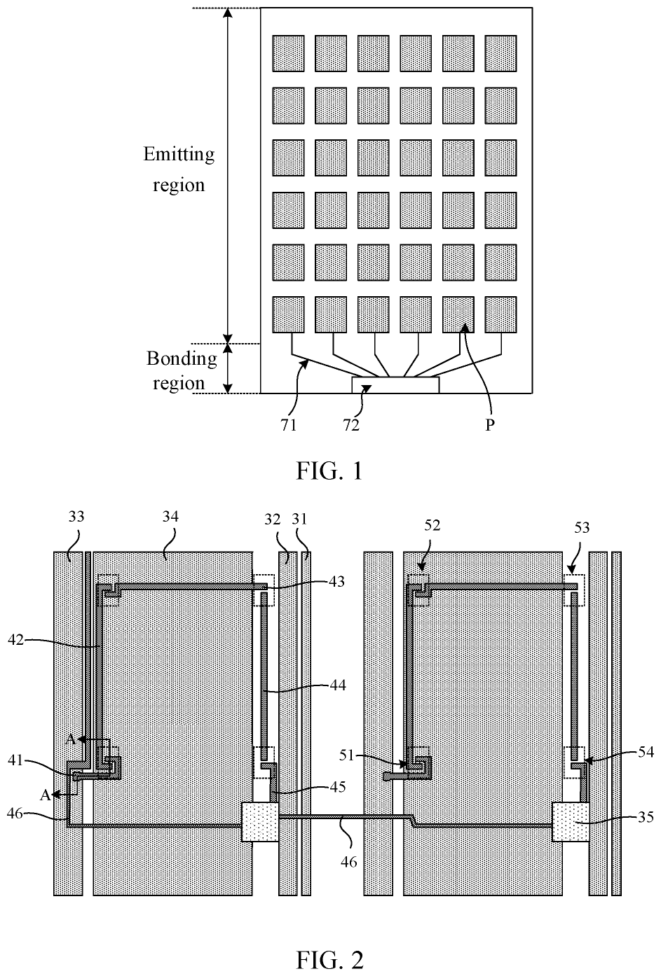

FIG. 1 is a schematic diagram of a structure of a driving backplane. As shown in FIG. 1, in an exemplary embodiment, in a plane parallel to the driving backplane, the driving backplane may include an emitting region and a bonding region. The bonding region may be located on one or more sides of the emitting region. In an exemplary embodiment, the emitting region may include multiple emitting units P which are arranged regularly. The bonding region may include multiple leads 71 and a bonding pad 72. One terminal of at least one of the leads 71 is connected with a driving circuit in at least one of the emitting units P, while the other terminal is connected with the bonding pad 72. In an exemplary embodiment, the bonding pad 72 is arranged to be connected with an external control circuit through a Flexible Printed Circuit (FPC), and the control circuit controls the corresponding emitting units to emit light.

In an exemplary embodiment, a shape of the emitting region may be set as required. For example, an outline of the emitting region may be a rectangle, and a shape of the emitting unit may also be a rectangle, so that it is easier to implement the regional control over a backlight source.

As a planar schematic diagram of a structure of an emitting unit in a driving backplane, FIG. 2 illustrates a structure of two emitting units in the driving backplane. As shown in FIG. 2, in an exemplary embodiment, in a plane parallel to the driving backplane, at least one emitting unit may include a first control line 31, a second control line 32, a driving voltage line 33, a common voltage line 34, a circuit pad 35, and multiple connection lines. In an exemplary embodiment, the first control line 31 is arranged to provide a first signal for the emitting unit. The first signal may be an address signal. The second control line 32 is arranged to provide a second signal for the emitting unit. The second signal may be a time length signal. The driving voltage line 33 is arranged to provide a driving voltage signal for the emitting unit. The common voltage line 34 is arranged to provide a common voltage signal for the emitting unit. The common voltage signal may be a ground signal. The circuit pad 35 is arranged to form a bonding connection with a Display Drive Integrated Circuit (DDIC). In an exemplary embodiment, the multiple connection lines may include a first connection line 41, a second connection line 42, a third connection line 43, a fourth connection line 44, a fifth connection line 45, and a sixth connection line 46.

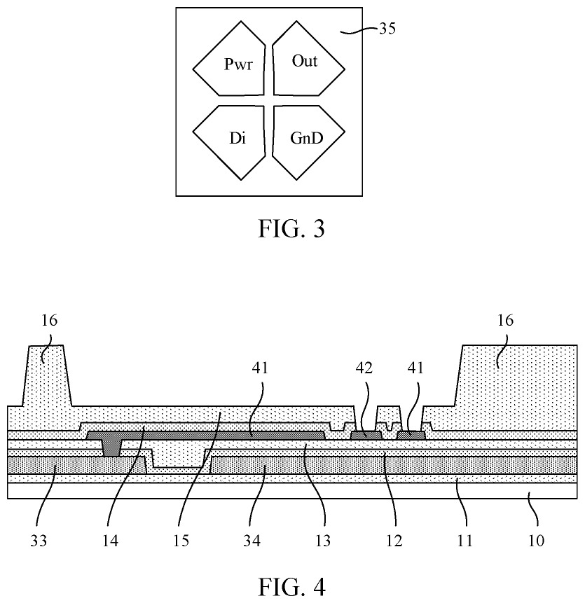

FIG. 3 is an enlarged view of a circuit pad in FIG. 2. As shown in FIG. 3, in an exemplary embodiment, the circuit pad 35 may include a first input terminal Di, a second input terminal Pwr, an output terminal Out, and a common voltage terminal Gnd. The first input terminal Di is connected with the first control line 31 and arranged to receive a first signal provided by the first control line 31. The first signal is, for example, an address signal used to gate the emitting unit at a corresponding address. Addresses of different emitting units in the multiple emitting units of the driving backplane may be the same or different. The address signal may be an 8-bit signal. The display drive integrated circuit may obtain an address to be transmitted by parsing the address signal. The second input terminal Pwr is connected with the second control line 32 and arranged to receive a second signal. The second signal is, for example, a carrier signal and a time length signal. The carrier signal may provide electric power for the display drive integrated circuit. The time length signal may control an emitting time length of the emitting unit to further control visual brightness thereof. The common voltage terminal Gnd is connected with the common voltage line 34 and arranged to receive a common voltage signal. The output terminal Out is arranged to output a driving signal and a relay signal. The driving signal may be a driving current used to drive an emitting element to emit light. The relay signal may be an address signal provided for other emitting units. The other emitting units receive the relay signal as an input signal, thereby obtaining the address signal.

As shown in FIG. 2, in an exemplary embodiment, a first terminal of the first connection line 41 is connected with the driving voltage line 33 through a via. A second terminal of the first connection line 41 extends to a first transistor fixing region 51 and forms a first terminal in the first transistor fixing region 51. A first terminal of the second connection line 42 is arranged in the first transistor fixing region 51 and forms a second terminal in the first transistor fixing region 51. The first terminal and second terminal of the first transistor fixing region 51 are spaced oppositely and arranged to respectively connect two electrodes of a first light emitting diode that is subsequently transferred to implement the connection between the first light emitting diode and the driving backplane. In an exemplary embodiment, a transistor fixing region refers to a region where electrodes of a light emitting diode are fixed.

In an exemplary embodiment, a second terminal of the second connection line 42 extends to a second transistor fixing region 52 and forms a first terminal in the second transistor fixing region 52. A first terminal of the third connection line 43 is arranged in the second transistor fixing region 52 and forms a second terminal in the second transistor fixing region 52. The first terminal and second terminal of the second transistor fixing region 52 are spaced oppositely and arranged to respectively connect two electrodes of a second light emitting diode that is subsequently transferred to implement the connection between the second light emitting diode and the driving backplane.

In an exemplary embodiment, a second terminal of the third connection line 43 extends to a third transistor fixing region 53 and forms a first terminal in the third transistor fixing region 53. A first terminal of the fourth connection line 44 is arranged in the third transistor fixing region 53 and forms a second terminal in the third transistor fixing region 53. The first terminal and second terminal of the third transistor fixing region 53 are spaced oppositely and arranged to respectively connect two electrodes of a third light emitting diode that is subsequently transferred to implement the connection between the third light emitting diode and the driving backplane.

In an exemplary embodiment, a second terminal of the fourth connection line 44 extends to a fourth transistor fixing region 54 and forms a first terminal in the fourth transistor fixing region 54. A first terminal of the fifth connection line 45 is arranged in the fourth transistor fixing region 54 and forms a second terminal in the fourth transistor fixing region 54. The first terminal and second terminal of the fourth transistor fixing region 54 are spaced oppositely and arranged to respectively connect two electrodes of a fourth light emitting diode that is subsequently transferred to implement the connection between the fourth light emitting diode and the driving backplane.

In an exemplary embodiment, a second terminal of the fifth connection line 45 extends to a region where the circuit pad 35 is located, and is connected with the output terminal Out in the circuit pad 35. As such, four light emitting diodes connected in series may be mounted through multiple connection lines in an emitting unit. In an exemplary embodiment, multiple, e.g., 5, 6, and 8, light emitting diodes may be mounted in an emitting unit. The multiple emitting units are arranged in any manner. No limits are made for the number of light emitting diodes and the arrangement thereof in the present disclosure.

In an exemplary embodiment, the sixth connection line 46 is arranged to transmit the first signal as an address translation line. For example, the driving backplane may include totally M*N of emitting unit groups of M rows and N columns. Each emitting unit group includes multiple emitting units. The multiple emitting units of each emitting unit group are sequentially numbered according to distribution positions in the rows and the columns. Only a first input terminal Di of a circuit pad 35 in the emitting unit numbered as 1 is connected with a first control line 31 through a connection line, and first input terminals Di of other emitting units receive a relay signal output by an output terminal Out of the previous emitting unit as a first input signal. For example, a first input terminal Di of a circuit pad 35 in the emitting unit numbered as n is connected with an output terminal Out of a circuit pad 35 in the emitting unit numbered as n−1 through a sixth connection line 46, and the first input terminal Di of the emitting unit numbered as n receives a relay signal output by the output terminal Out of the emitting unit numbered as n−1 as a first signal. For another example, the output terminal Out of the circuit pad 35 in the emitting unit numbered as n is connected with a first input terminal Di of a circuit pad 35 of the emitting unit numbered as n+1 through a sixth connection line 46. Accordingly, for an emitting unit group, only a connection line is needed to provide a first signal (address signal) such that all emitting units in the emitting unit group may obtain respective address signals, greatly reducing the number of signal lines, reducing a wiring space, and simplifying a control mode.

In an exemplary embodiment, the emitting unit may use a two-period driving mode. In a first period, the emitting unit may output a relay signal through the output terminal Out according to a first signal received by the first input terminal Di and a second signal received by the second input terminal Pwr. In a second period, the emitting unit may provide, through the output terminal Out a driving signal to multiple light emitting diodes sequentially connected in series. For example, in the first period, the output terminal Out outputs the relay signal, and the relay signal is provided for other emitting units such that the other emitting units obtain the address signal. In the second period, the output terminal Out outputs the driving signal, and the driving signal is provided for the multiple light emitting diodes sequentially connected in series such that the light emitting diodes emit light in the second period. In an exemplary embodiment, the first period is different from the second period, and the first period may be earlier than the second period. For example, the first period and the second period may be consecutive, and an ending moment of the first period is a starting moment of the second period. For another example, there may also be another period between the first period and the second period, and the another period may be used to realize another function, or may be only used to separate the first period from the second period to avoid interferences between the signals output by the output terminal Out in the first period and the second period.

In an exemplary embodiment, the number and arrangement of emitting unit groups on the driving backplane, the number and arrangement of multiple emitting units in the emitting unit group, the number and arrangement of multiple light emitting diodes in the emitting unit, etc., may be set according to a practical situation and will not be limited in the present disclosure.

The driving backplane of the exemplary embodiment of the present disclosure may include a driving structure layer arranged on a base and a supporting structure arranged on a side of the driving structure layer away from the base. The driving structure layer includes a first conductive layer and second conductive layer which are stacked. There is no overlapping region between an orthographic projection of the supporting structure on the base and an orthographic projection of at least one of the first conductive layer and the second conductive layer on the base. FIG. 4 is a schematic diagram of a sectional structure of an emitting unit in a driving backplane according to an exemplary embodiment of the present disclosure, and is a sectional view along direction A-A in FIG. 2. As shown in FIGS. 2 and 4, in the exemplary embodiment, in a plane perpendicular to the driving backplane, the driving backplane may include a base 10, a first insulating layer 11 arranged on the base 10, a first conductive layer arranged on the first insulating layer 11, a second insulating layer 12 arranged on the first conductive layer, a third insulating layer 13 arranged on the second insulating layer 12, a second conductive layer arranged on the third insulating layer 13, a fourth insulating layer 14 arranged on the second conductive layer, a fifth insulating layer 15 arranged on the fourth insulating layer 14, and a supporting structure 16 arranged on the fifth insulating layer 15. In an exemplary embodiment, the first insulating layer 11, the first conductive layer, the second insulating layer 12, the third insulating layer 13, the second conductive layer, the fourth insulating layer 14 and the fifth insulating layer 15 form the driving structure layer of the present disclosure.

In an exemplary embodiment, the first conductive layer may include a first control line 31, a second control line 32, a driving voltage line 33, and a common voltage line 34.

In an exemplary embodiment, the second conductive layer may include a first connection line 41, a second connection line 42, a third connection line 43, a fourth connection line 44, a fifth connection line 45, a sixth connection line 46, a first input terminal Di, a second input terminal Pwr, an output terminal Out, and a common voltage terminal Gnd.

In an exemplary embodiment, first vias are formed in the second insulating layer 12 and the third insulating layer 13. The first connection line 41 in the second conductive layer 22 is connected with the driving voltage line 33 of the first conductive layer 21 through the first via.

In an exemplary embodiment, the first insulating layer 11, the second insulating layer 12 and the fourth insulating layer 14 are inorganic insulating layers, may use any one or more of silicon oxide (SiOx), silicon nitride (SiNx) and silicon oxynitride (SiON), and may be single-layer, multilayer or composite. The first insulating layer is called a buffer layer. The second insulating layer is called a Gate Insulator (GI) layer. The fourth insulating layer is called a passivation (PVX) layer. The third insulating layer 13 and the fifth insulating layer 15 are organic insulating layers and may use organic materials, e.g., a resin. The first conductive layer 21 and the second conductive layer 22 may use metal materials, e.g., any one or more of Copper (Cu), Aluminum (Al), Titanium (Ti), Molybdenum (Mo), Chromium (Cr), and Tungsten (W), or alloy materials of the above-mentioned metals, e.g., Aluminum-Neodymium (AlNd) or Molybdenum-Niobium (MoNb), and may be single-layer structures, or multilayer composite structures such as MoNb/Cu/MoNb.

In an exemplary embodiment, there is no overlapping region between an orthographic projection of the supporting structure 16 on the base and an orthographic projection of the first conductive layer on the base.

In an exemplary embodiment, there is no overlapping region between an orthographic projection of the supporting structure 16 on the base and an orthographic projection of the second conductive layer on the base.

In an exemplary embodiment, there is no overlapping region between an orthographic projection of the supporting structure 16 on the base and each of an orthographic projection of the first conductive layer 21 on the base and an orthographic projection of the second conductive layer on the base.

In an exemplary embodiment, the supporting structure 16 may use an organic material, e.g., a resin.

In an exemplary embodiment, the supporting structure 16 and the fifth insulating layer 15 are formed by two patterning processes based on ordinary masks respectively.

In an exemplary embodiment, the supporting structure 16 and the fifth insulating layer 15 are simultaneously formed by one patterning process based on a gray tone mask.

In an exemplary embodiment, a distance between a surface of a side of the supporting structure 16 away from the base and a surface of a side of the fifth insulating layer 15 away from the base may be about 10 μm to 50 μm.

In an exemplary embodiment, the supporting structure 16 may include any one or more of a supporting column and a supporting dam.

In an exemplary embodiment, the supporting structure 16 may use different structures at different positions of the driving backplane. For example, the supporting structure 16 may use a supporting column structure in a region where an emitting unit is located and use a supporting dam structure in a region between adjacent emitting units. In an exemplary embodiment, the supporting structure 16 may be of different shapes at different positions of the driving backplane. For example, the supporting structure 16 may use a supporting column with a plane of a round or elliptical plane shape in a region where a light emitting diode is located and use a supporting column with a plane of a rectangular or polygonal plane shape in a region outside region where a light emitting diode is located. In an exemplary embodiment, the supporting structure 16 may be of different sizes at different positions of the driving backplane. For example, the supporting structure 16 may use a supporting dam with a relatively large width in an emitting region and use a supporting dam with a relatively small width in a bonding region. In an exemplary embodiment, the structure, shape, size and the like of the supporting structure 16 on the driving backplane may be set as practically required and will not be limited in the present disclosure.

A preparation process of the driving backplane will be exemplarily described below. A “patterning process” mentioned in the present disclosure includes coating with a photoresist, mask exposure, development, etching, photoresist stripping, etc. for a metal material, an inorganic material, or a transparent conductive material, and includes coating with an organic material, mask exposure, development, etc. for the organic material. Deposition may be any one or more of sputtering, evaporation, and chemical vapor deposition. Coating may be any one or more of spray coating, spin coating, and ink-jet printing. Etching may be any one or more of dry etching and wet etching. No limits are made in the present disclosure. “Thin film” refers to a layer of thin film made from a certain material on a base by deposition, coating, or another process. If the patterning process is not needed by the “thin film” in the whole making process, the “thin film” may also be called a “layer”. If the patterning process is needed by the “thin film” in the whole making process, the thin film is called a “thin film” before the patterning process and called a “layer” after the patterning process. The “layer” after the patterning process includes at least one “pattern”. “A and B are arranged in the same layer” mentioned in the present disclosure refers to that A and B are simultaneously formed by the same patterning process. The “thickness” of the film layer is a size of the film layer in a direction perpendicular to the driving backplane. In the exemplary embodiment of the present disclosure, “the orthographic projection of A includes the orthographic projection of B” refers to that a boundary of the orthographic projection of B falls within a range of a boundary of the orthographic projection of A or the boundary of the orthographic projection of A is overlapped with the boundary of the orthographic projection of B.

In an exemplary implementation, the preparation process of the driving backplane may include the following operations.

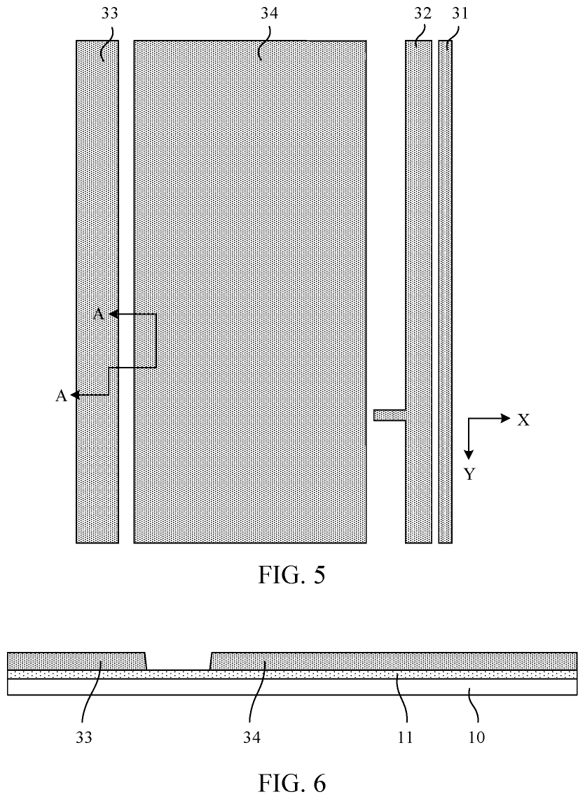

(1) A pattern of a first conductive layer is formed. In an exemplary implementation, forming a first conductive layer may include that: a first insulating thin film and a first metal thin film are sequentially deposited on a base, and the first metal thin film is patterned by a patterning process to form a first insulating layer 11 arranged on the base 10 and the pattern of the first conductive layer arranged on the first insulating layer 11. The pattern of the first conductive layer at least includes a first control line 31, a second control line 32, a driving voltage line 33, and a common voltage line 34, as shown in FIGS. 5 and 6. FIG. 6 is a sectional view along direction A-A in FIG. 5.

In an exemplary implementation, the driving voltage line 33, the common voltage line 34, the second control line 32 and the first control line 31 may be sequentially arranged in a first direction X and extend in a second direction Y. The first control line 31, the second control line 32, the driving voltage line 33 and the common voltage line 34 may be straight lines with equal widths. The width of the common voltage line 34 may be greater than that of the driving voltage line 33. The width of the driving voltage line 33 may be greater than those of the first control line 31 and the second control line 32. The width is a size in the first direction X.

In an exemplary implementation, a protrusion is arranged on a side of the second control line 32 close to the common voltage line 34. The protrusion may be arranged to be connected with a second input terminal Pwr of a subsequently formed circuit pad through a via.

In an exemplary implementation, the first insulating thin film may be deposited by Chemical Vapor Deposition (CVD), and the first metal thin film may be deposited by magnetron sputtering.

In an exemplary implementation, the first conductive layer may be a multilayer composite structure, including a first sublayer (underlayer on a side close to the base), a second sublayer (middle layer), and a third sublayer (top layer on a side away from the base). The first sublayer may use Molybdenum-Niobium (MoNb) for improving the adhesive power. The second sublayer may use Copper (Cu) for reducing resistance. The third sublayer may use MoNb for resisting oxidation. Therefore, a stacked MoNb/Cu/MoNb structure is formed.

In an exemplary implementation, an overall thickness of the first conductive layer may be about 1.5 μm to 7 μm. According to the law of resistance, resistance is lower if a cross sectional area of a wire is larger. Therefore, if the first conductive layer is relatively thick, the resistance may be reduced, and the electrical performance may be improved.

In an exemplary implementation, a thickness of the first sublayer may be about 200 Å to 400 Å, e.g., 300 Å. A thickness of the third sublayer may be about 100 Å to 300 Å, e.g., 200 Å.

In an exemplary implementation, the present process may also be implemented in the following manner. The first insulating thin film is deposited at first on the base to form the first insulating layer arranged on the base. Then, the first sublayer is prepared on the first insulating layer as a seed layer, to improve the grain nucleation density. Next, the second sublayer is electroplated on the first sublayer by an electroplating process. Finally, the third sublayer is prepared on the second sublayer as an anti-oxidation layer. The first sublayer may use MoNiTi. The second sublayer may use Copper (Cu). The third sublayer may use MoNiTi.

In an exemplary embodiment, the base may use a rigid base or a flexible base. The rigid base may be glass, etc. The flexible base may be Polyimide (PI), etc.

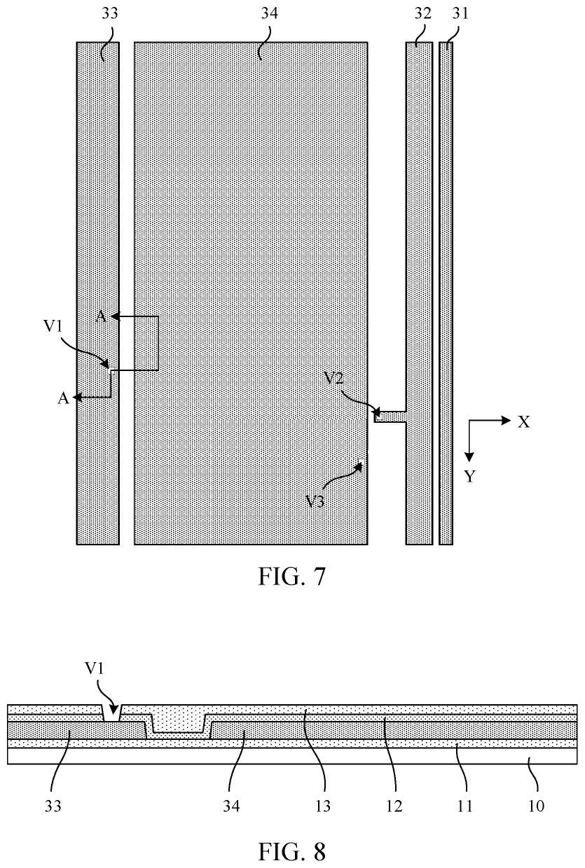

(2) Patterns of a second insulating layer and a third insulating layer are formed. In an exemplary implementation, forming patterns of the second insulating layer and the third insulating layer may include that: a second insulating thin film is deposited at first on the base where the above-mentioned pattern is formed, to form the pattern of the second insulating layer 12 covering the pattern of the first conductive layer, then a layer of third insulating thin film is coated to form the third insulating layer 13 on the second insulating layer 12, and the second insulating layer 12 and the third insulating layer 13 are patterned by a patterning process to form patterns of multiple vias. The multiple vias may at least include a first via V1, a second via V2, and a third via V3, as shown in FIGS. 7 and 8. FIG. 8 is a sectional view along direction A-A in FIG. 7.

In an exemplary implementation, the third insulating layer 13 and second insulating layer 12 in the first via V1 are removed to expose a surface of the driving voltage line 33. The first via V1 is arranged to connect a subsequently formed first connection line 41 with the driving voltage line 33. The third insulating layer 13 and second insulating layer 12 in the second via V2 are removed to expose a surface of the protrusion in the second control line 32. The second via V2 is arranged to connect the subsequently formed second input terminal Pwr with the second control line 32. The third insulating layer 13 and second insulating layer 12 in the third via V3 are removed to expose a surface of the common voltage line 34. The third via V3 is arranged to connect a subsequently formed common voltage terminal Gnd with the common voltage line 34.

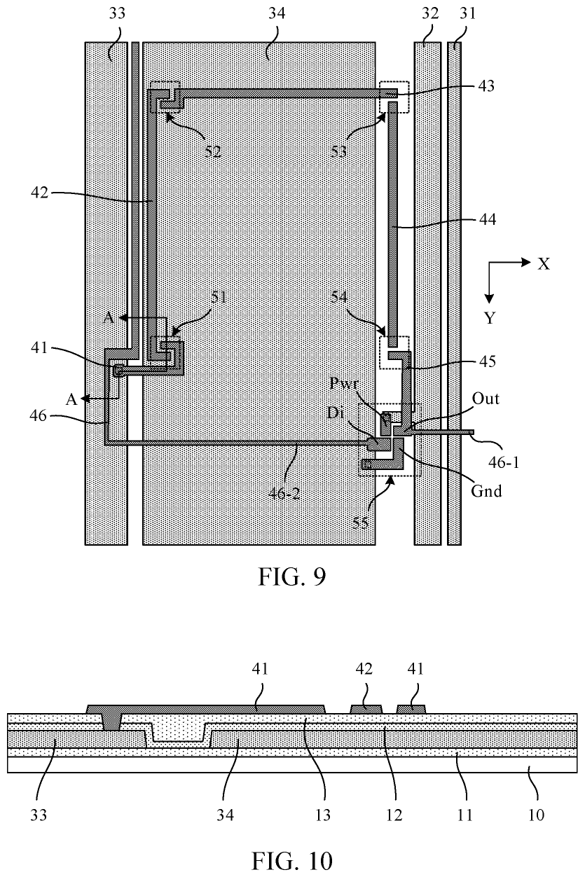

(3) A pattern of a second conductive layer is formed. In an exemplary implementation, forming the pattern of the second conductive layer may include that: a second metal thin film is deposited on the base where the above-mentioned patterns are formed, and the second metal thin film is patterned by a patterning process to form the pattern of the second conductive layer on the third insulating layer 13. The pattern of the second conductive layer at least includes the first connection line 41, a second connection line 42, a third connection line 43, a fourth connection line 44, a fifth connection line 45, a sixth connection line 46, a first input terminal Di, the second input terminal Pwr, an output terminal Out, and the common voltage terminal Gnd, as shown in FIGS. 9 and 10. FIG. 10 is a sectional view along direction A-A in FIG. 9.

In an exemplary implementation, the fifth connection line 45 and the output terminal Out are mutually connected into an integrated structure. The first input terminal Di, second input terminal Pwr, output terminal Out and common voltage terminal Gnd on a pad region 55 form a circuit pad arranged to be connected with a Display Drive Integrated Circuit (DDIC).

In an exemplary implementation, a first terminal of the first connection line 41 is located in a region where the driving voltage line 33 is located, and is connected with the driving voltage line 33 through the first via V1. A second terminal of the first connection line 41 extends to a first transistor fixing region 51 in the first direction X.

In an exemplary implementation, a first terminal of the second connection line 42 is located in the first transistor fixing region 51 and arranged opposite to the second terminal of the first connection line 41. A second terminal of the second connection line 42 extends to a second transistor fixing region 52 in a direction opposite to the second direction Y.

In an exemplary implementation, a first terminal of the third connection line 43 is located in the second transistor fixing region 52 and arranged opposite to the second terminal of the second connection line 42. A second terminal of the third connection line 43 extends to a third transistor fixing region 53 in the first direction X.

In an exemplary implementation, a first terminal of the fourth connection line 44 is located in the third transistor fixing region 53 and arranged opposite to the second terminal of the third connection line 43. A second terminal of the fourth connection line 44 extends to a fourth transistor fixing region 54 in the second direction Y.

In an exemplary implementation, a first terminal of the fifth connection line 45 is located in the fourth transistor fixing region 54 and arranged opposite to the second terminal of the fourth connection line 44. A second terminal of the fifth connection line 45 extends to the pad region 55 in the second direction Y and forms the output terminal Out in the pad region 55.

In an exemplary implementation, the second terminal of the first connection line 41 and the first terminal of the second connection line 42, which are arranged oppositely in the first transistor fixing region 51, form two electrode terminals for fixing a first light emitting diode that is subsequently transferred. The second terminal of the first connection line 41 may be connected with a cathode (electrode N) of the first light emitting diode as a cathode terminal. The first terminal of the second connection line 42 may be connected with an anode (electrode P) of the first light emitting diode as an anode terminal.

In an exemplary implementation, the second terminal of the second connection line 42 and the first terminal of the third connection line 43, which are arranged oppositely in the second transistor fixing region 52, form two electrode terminals for fixing a second light emitting diode that is subsequently transferred. The second terminal of the second connection line 42 may be connected with a cathode (electrode N) of the second light emitting diode as a cathode terminal. The first terminal of the third connection line 43 may be connected with an anode (electrode P) of the second light emitting diode as an anode terminal.

In an exemplary implementation, the second terminal of the third connection line 43 and the first terminal of the fourth connection line 44, which are arranged oppositely in the third transistor fixing region 53, form two electrode terminals for fixing a third light emitting diode that is subsequently transferred. The second terminal of the third connection line 43 may be connected with a cathode (electrode N) of the third light emitting diode as a cathode terminal. The first terminal of the fourth connection line 44 may be connected with an anode (electrode P) of the third light emitting diode as an anode terminal.

In an exemplary implementation, the second terminal of the fourth connection line 44 and the first terminal of the fifth connection line 45, which are arranged oppositely in the fourth transistor fixing region 54, form two electrode terminals for fixing a fourth light emitting diode that is subsequently transferred. The second terminal of the fourth connection line 44 may be connected with a cathode (electrode N) of the fourth light emitting diode as a cathode terminal. The first terminal of the fifth connection line 45 may be connected with an anode (electrode P) of the fourth light emitting diode as an anode terminal.

In an exemplary implementation, all the cathode terminals in the first transistor fixing region 51 to the fourth transistor fixing region 54 may be located on one side of the anode terminals in the direction opposite to the second direction Y. Alternatively, all the cathode terminals in the first transistor fixing region 51 to the fourth transistor fixing region 54 may be located on one side of the anode terminals in the second direction Y. The light emitting diodes are longitudinally mounted, so that the display effect may be improved.

In an exemplary implementation, the sixth connection line 46 may include a first terminal 46-1, polyline and second terminal 46-2 which are sequentially connected. A first terminal 46-1 of a sixth connection line 46 of a present emitting unit (numbered as n) is located in a pad region 55 and forms an output terminal Out in the pad region 55, namely the first terminal 46-1 and the output terminal Out are mutually connected into an integrated structure. The first terminal 46-1 of the present emitting unit is connected with a second terminal of a sixth connection line of a next emitting unit (numbered as n+1) through a polyline. A second terminal 46-2 of the sixth connection line 46 of the present emitting unit (numbered as n) is located in the pad region 55 and forms a first input terminal Di in the pad region 55, namely the second terminal 46-2 and the first input terminal Di are mutually connected into an integrated structure. The second terminal 46-2 of the present emitting unit is connected with a first terminal of a sixth connection line of a previous emitting unit (numbered as n−1) through the polyline.

In an exemplary implementation, both the second input terminal Pwr and the common voltage terminal Gnd are located in the pad region 55. The second input terminal Pwr is connected with the second control line 32 through the second via V2. The common voltage terminal Gnd is connected with the common voltage line 34 through the third via V3.

In an exemplary implementation, the second conductive layer may use a single-layer structure or a multilayer structure. For example, the single-layer structure may use copper, and a thickness may be about 6,000 Å. For another example, the multilayer structure may use stacked MoNb/Cu/CuNi. For stacked MoNb/Cu/CuNi structure, an underlayer may use Molybdenum-Niobium (MoNb) to improve the adhesive power, and a thickness of Molybdenum-Niobium (MoNb) may be about 200 Å to 400 Å, e.g., 300 Å. A top layer may use Copper-Nickel (CuNi) to resist oxidation and ensure the transistor fixing fastness, and a thickness of Copper-Nickel (CuNi) may be about 500 Å to 1,000 Å. In an exemplary implementation, the top layer may also use Nickel (Ni) or Indium Tin Oxide (ITO). No limits are made in the present disclosure.

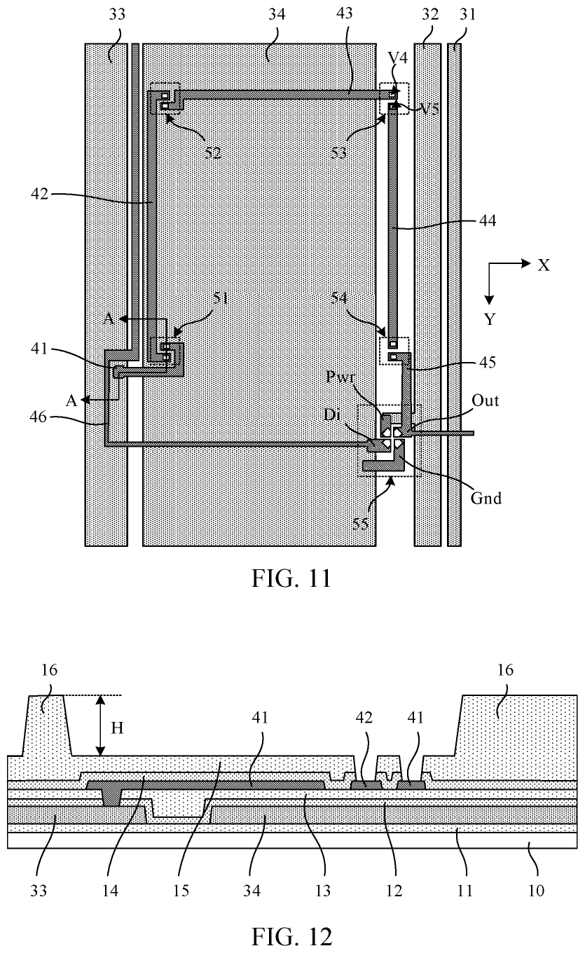

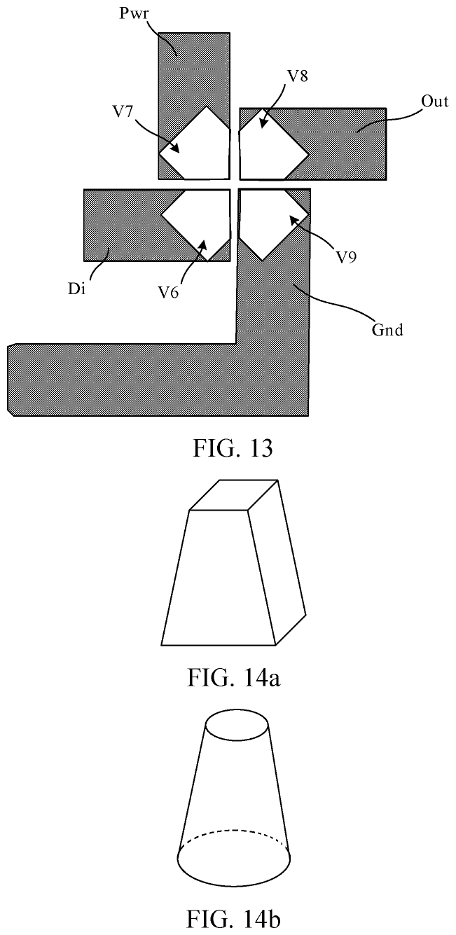

(4), Patterns of a fifth insulating layer and a supporting structure are formed. In an exemplary implementation, forming patterns of the fifth insulating layer and the supporting structure may include that: a fourth insulating thin film is deposited at first on the base where the above-mentioned patterns are formed, to form the pattern of the fourth insulating layer 14 covering the pattern of the second conductive layer, then a layer of fifth insulating thin film is coated, and the fifth insulating thin film is patterned by a patterning process to form the pattern of the fifth insulating layer 15 on the fourth insulating layer 14. The supporting structure 16 is formed on the fifth insulating layer 15. Patterns of multiple vias are formed on the fourth insulating layer 14 and the fifth insulating layer 15. The multiple vias may include multiple fourth vias V4, multiple fifth vias V5, a sixth via V6, a seventh via V7, an eighth via V8, and a ninth via V9, as shown in FIGS. 11, 12 and 13. FIG. 12 is a sectional view along direction A-A in FIG. 11. FIG. 13 is an enlarged view of a pad region in FIG. 11.

In an exemplary implementation, the above-mentioned first insulating layer, first conductive layer, second insulating layer, third insulating layer, second conductive layer, fourth insulating layer and fifth insulating layer form the driving structure layer of the present disclosure.

In an exemplary embodiment, a distance H between a surface of a side of the supporting structure 16 away from the base and a surface of a side of the fifth insulating layer 15 away from the base may be about 10 μm to 50 μm.

In an exemplary implementation, the multiple fourth vias V4 are located in regions where the cathode terminals are located in the first transistor fixing region 51 to the fourth transistor fixing region 54 respectively. The fifth insulating layer 15 and fourth insulating layer 14 in the fourth vias V4 are removed to expose surfaces of the cathode terminals. The multiple fifth vias V5 are located in regions where the anode terminals are located in the first transistor fixing region 51 to the fourth transistor fixing region 54 respectively. The fifth insulating layer 15 and fourth insulating layer 14 in the fifth vias V5 are removed to expose surfaces of the anode terminals. In a light emitting diode that is subsequently transferred, two electrode terminals of the light emitting diode are fixedly connected with the cathode terminal and the anode terminal through the fourth via V4 and the fifth via V5 respectively.

In an exemplary implementation, the sixth via V6 is located in a region where the first input terminal Di is located in the pad region 55. The fifth insulating layer 15 and fourth insulating layer 14 in the sixth via V6 are removed to expose a surface of the first input terminal Di. The seventh via V7 is located in a region where the second input terminal Pwr is located in the pad region 55. The fifth insulating layer 15 and fourth insulating layer 14 in the seventh via V7 are removed to expose a surface of the second input terminal Pwr. The eighth via V8 is located in a region where the output terminal Out is located in the pad region 55. The fifth insulating layer 15 and fourth insulating layer 14 in the eighth via V8 are removed to expose a surface of the output terminal Out. The ninth via V9 is located in a region where the common voltage terminal Gnd is located in the pad region 55. The fifth insulating layer 15 and fourth insulating layer 14 in the ninth via V9 are removed to expose a surface of the common voltage terminal Gnd. When the Display Drive Integrated Circuit (DDIC) is subsequently mounted, one of four pins of the Display Drive Integrated Circuit (DDIC) is fixedly connected with the first input terminal Di through the sixth via V6, another of the four pins is fixedly connected with the second input terminal Pwr through the seventh via V7, yet another of the four pins is fixedly connected with the output terminal Out through the eighth via V8, and the last one of the four pins is fixedly connected with the common voltage terminal Gnd through the ninth via V9.

In an exemplary implementation, the supporting structure 16 may include any one or more of multiple supporting columns and/or multiple supporting dams.

FIGS. 14a and 14b are schematic diagrams of structures of a supporting column according to an exemplary embodiment of the present disclosure. In an exemplary implementation, the supporting column may be a columnar body, and a plane shape of the columnar body may be a rectangle, as shown in FIG. 14a, or may be a round, as shown in FIG. 14b.

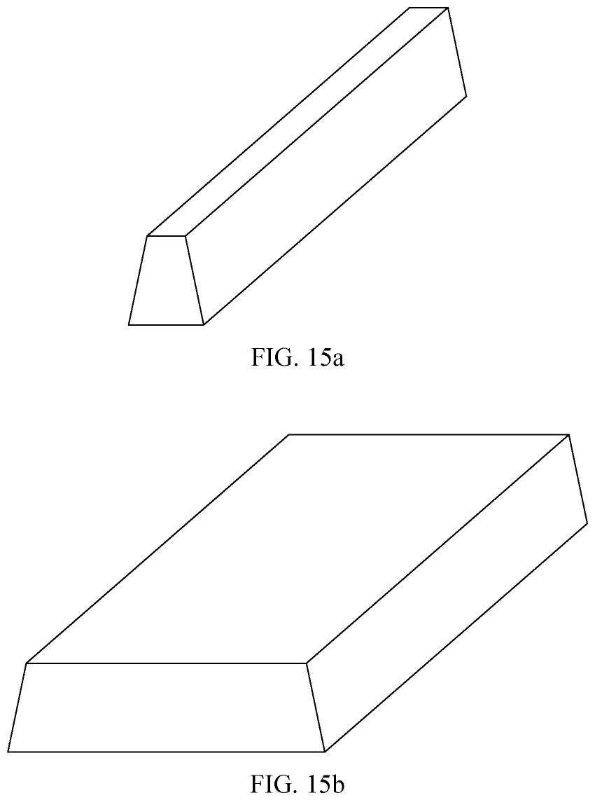

FIGS. 15a and 15b are schematic diagrams of structures of a supporting dam according to an exemplary embodiment of the present disclosure. In an exemplary implementation, the supporting dam may be a strip-type body extending in a certain direction, as shown in FIG. 15a, or may be a planar body extending in two certain directions, as shown in FIG. 15b.

In an exemplary embodiment, since the supporting column and the supporting dam are arranged to avoid particles being squeezed in subsequent screen printing and soldering processes and a film layer damage due to squeezing on particles, heights of the supporting column and the supporting dam may be set to be greater than sizes of the particles. Considering that sizes of particles generated in the preparation process are about less than 10 μm, the height of the supporting column may be set to about 10 μm to 50 μm in the present disclosure.

In an exemplary embodiment, since the supporting column and the supporting dam are arranged for supporting, a supporting effect is better if areas of the supporting column and the supporting dam are larger. In an exemplary embodiment, the supporting column and the supporting dam may be arranged in a gap region where the first conductive layer and the second conductive layer are not arranged. In order to improve the supporting effect, widths of the supporting column and the supporting dam may be set to be greater than a width of the corresponding gap region. Considering that a minimum width of the corresponding gap region is about 10 μm, in the present disclosure the width of the supporting column is set to be about 10 μm to 100 μm and the width of the supporting dam is set to be about 100 μm to 1,000 μm.

In an exemplary implementation, in a plane parallel to the driving backplane, the supporting structure may be an isolated structure, or a polyline structure, or a closed circinal structure. For example, the multiple supporting columns or supporting dams may be spaced, and each supporting column or supporting dam is an isolated structure. For another example, the multiple supporting dams may be sequentially connected to form a polyline structure. For another example, the multiple supporting dams may be sequentially connected to form a closed circinal structure.

In an exemplary implementation, in a plane parallel to the driving backplane, a sectional shape of the supporting column may be any one or more of a triangle, a rectangle, a polygon, a round, and an ellipse. In a plane perpendicular to the driving backplane, a sectional shape of the supporting column may be any one or more of a triangle, a rectangle, and a trapezoid.

In an exemplary embodiment, there is no overlapping region between an orthographic projection of the supporting structure 16 on the base and an orthographic projection of the second conductive layer on the base.

In another exemplary embodiment, there is no overlapping region between an orthographic projection of the supporting structure 16 on the base and an orthographic projection of the first conductive layer on the base.

In another exemplary embodiment, there is no overlapping region between an orthographic projection of the supporting structure 16 on the base and each of an orthographic projection of the first conductive layer 21 on the base and an orthographic projection of the second conductive layer on the base.

In an exemplary embodiment, the supporting structure 16 may use an organic material, e.g., a resin.

In an exemplary embodiment, the patterns of the fifth insulating layer and the supporting structure may be formed by one process based on a gray tone mask. For example, the process based on a gray tone mask may include the following operations. After the fifth insulating thin film is coated, the fifth insulating thin film is exposed and developed using a gray tone mask to form a completely exposed region, a partially exposed region and an unexposed region. The fifth insulating thin film in the completely exposed region is removed to expose the fourth insulating layer 14. A thickness of the fifth insulating thin film in the partially exposed region is partially removed to form a first thickness. The fifth insulating thin film in the unexposed region is retained. The fifth insulating thin film in the partially exposed region has a second thickness. The first thickness is less than the second thickness. Then, the fourth insulating layer 14 in organic holes is etched by a dry etch process to form patterns of multiple vias in the completely exposed region, the pattern of the fifth insulating layer in the partially exposed region and the pattern of the supporting structure in the unexposed region. Since the multiple vias and the supporting structure are formed by the same gray tone mask, the number of times for performing masking may be reduced, the process time may be shortened, and the production cost may be reduced effectively.

Hereto, the preparation of the driving backplane of the exemplary embodiment of the present disclosure is completed. The driving backplane includes the first insulating layer, first conductive layer, second insulating layer, third insulating layer, second conductive layer, fourth insulating layer, fifth insulating layer and supporting structure which are stacked on the base. The first conductive layer may include the first control line 31, the second control line 32, the driving voltage line 33, and the common voltage line 34. The second conductive layer 22 may include the first connection line 41 to the sixth connection line 46, the first input terminal Di, the second input terminal Pwr, the output terminal Out, and the common voltage terminal Gnd.

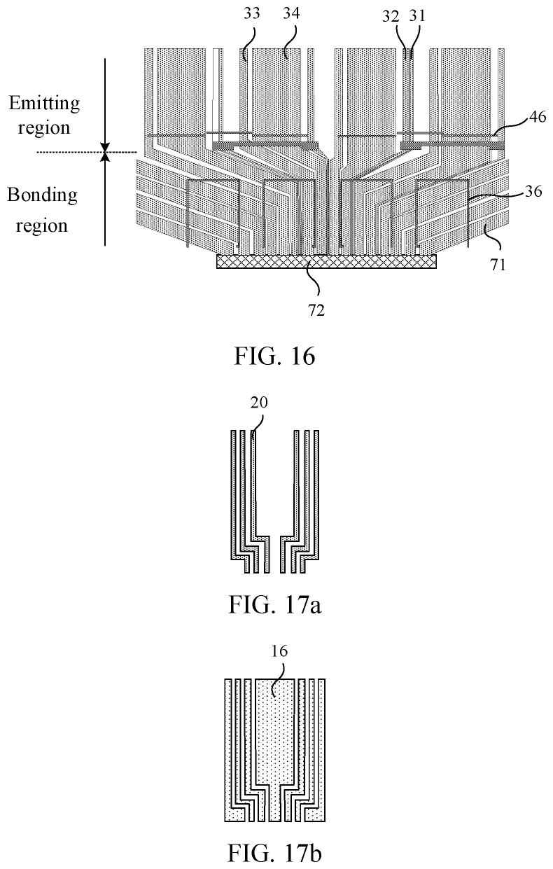

FIG. 16 is a planar schematic diagram of a structure of a bonding region in a driving backplane according to an exemplary embodiment of the present disclosure. As shown in FIG. 16, in a plane parallel to the driving backplane, the driving backplane may include an emitting region and a bonding region. The bonding region may be located on one side of the emitting region. The emitting region includes multiple emitting units which are arranged regularly. The bonding region may include multiple leads 71 and a bonding pad 72. The multiple leads 71 may include a lead integrated and connected with a first control line 31 in the emitting region, a lead integrated and connected with a second control line 32 in the emitting region, a lead integrated and connected with a driving voltage line 33 in the emitting region, and a lead integrated and connected with a common voltage line 34 in the emitting region. Terminal portions of sides of the multiple leads away from the emitting region are connected with the bonding pad 72.

In an exemplary embodiment, the bonding region may further include multiple connection lines 36. The connection lines 36 are arranged to be connected with the corresponding leads through corresponding vias. For example, the connection lines 36 may connect the leads transmitting the same signal. In an exemplary embodiment, the multiple leads 71 in the bonding region are arranged on a first conductive layer, and are arranged in the same layer as the first conductive layer of the emitting region, and are formed in the same patterning process simultaneously with the first conductive layer of the emitting region. The connection lines 36 are arranged on a second conductive layer, and are arranged in the same layer as and formed by the same patterning process simultaneously with the second conductive layer of the emitting region.

In an exemplary embodiment, the blank region in FIG. 16 is a region in which both the first conductive layer and the second conductive layer are not included. The supporting structure may be arranged in the above-mentioned blank region without overlapping with each of the first conductive layer and the second conductive layer such that there are no overlapping regions between an orthographic projection of the supporting structure on the base and orthographic projections of the first conductive layer and the second conductive layer on the base.

In an exemplary embodiment, the patterns of the fifth insulating layer and the supporting structure may be formed by a process based on two ordinary masks. For example, the process based on the two ordinary masks may include the following operations. After the fifth insulating thin film is coated, the fifth insulating thin film is exposed and developed at first using a first ordinary mask, and the fourth insulating layer is etched by an etching process to form patterns of multiple vias. Then, a sixth insulating thin film (supporting thin film) is coated, and the sixth insulating thin film is exposed and developed using a second ordinary mask to form the pattern of the supporting structure. The fifth insulating thin film and the sixth insulating thin film may use the same material or different materials. Alternatively, exposure and the like are directly performed on the fifth insulating thin film using the second ordinary mask without coating with the sixth insulating thin film.

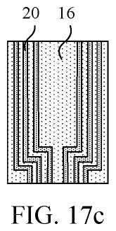

In an exemplary embodiment, the second ordinary mask may be a shared mask that may be used as a mask for patterning the first conductive layer. FIGS. 17a, 17b and 17c are schematic diagrams of sharing a mask according to an exemplary embodiment of the present disclosure. In an exemplary embodiment, a positive photoresist may be used in the process of patterning the first conductive layer using the mask for the first conductive layer, the positive photoresist being a photoresist capable of removing an exposed region after exposure and development, to form the pattern of the first conductive layer 20, as shown in FIG. 17a. In the subsequent patterning process of forming the supporting structure, the fifth insulating thin film or the sixth insulating thin film may use an organic material with a negative photoresist property, and the fifth insulating thin film or the sixth insulating thin film is still exposed and developed using the mask for the first conductive layer to remove a thin film in an unexposed region to form the pattern of the supporting structure 16, as shown in FIG. 17b. As such, the pattern of the first conductive layer and the pattern of the supporting structure, which are formed by the same mask for the first conductive layer, are complementary. That is, the pattern of the supporting structure is not in a region including the pattern of the first conductive layer on the driving backplane, the pattern of the first conductive layer is not in a region including the pattern of the supporting structure on the driving backplane, an orthographic projection of the region not including the pattern of the first conductive layer on the driving backplane on the base is overlapped with that of the pattern of the supporting structure on the base, and an orthographic projection of the region not including the pattern of the supporting structure on the driving backplane on the base is overlapped with that of the pattern of the first conductive layer on the base, as shown in FIG. 17c. For the supporting structure formed by the present process, there is no overlapping region between an orthographic projection of the supporting structure on the base and an orthographic projection of the first conductive layer on the base. Since the first conductive layer and the supporting structure are formed by the same mask, not only the mask preparation cost can be reduced, but also the mask replacement time can be shortened, and the production cost can be reduced effectively.

In an exemplary embodiment, a negative photoresist may be used in the process of forming the first conductive layer, and an organic material with a positive photoresist property may be used in the process of forming the supporting structure.

In an exemplary embodiment, the second ordinary mask may be a shared mask that may be used as a mask for patterning the second conductive layer. The pattern of the second conductive layer and the pattern of the supporting structure, which are formed by the same mask for the second conductive layer, are complementary.

It can be seen from the above-described structure and preparation flow of the driving backplane that, according to the driving backplane provided in the exemplary embodiment of the present disclosure, the supporting structure is arranged, and there is no overlapping region between the orthographic projection of the supporting structure on the base and the orthographic projection of at least one of the first conductive layer and the second conductive layer on the base, so that the first conductive layer and the second conductive layer will not be turned on when the supporting structure is squeezed in the subsequent screen printing and soldering processes, and the problems of short-circuit and the like are solved effectively. In addition, since there is no overlapping region between the orthographic projection of the supporting structure on the base and the orthographic projection of at least one of the first conductive layer and the second conductive layer on the base, water vapor may not corrode the conductive layers even if entering from a position at which a film layer is damaged in a region where the supporting structure is located, and the risk of short-circuit is reduced effectively. The preparation process of the driving backplane in the exemplary embodiment of the present disclosure is highly compatible with a present preparation process, and has advantages of simple in process implementation, easy to implement, high in production efficiency and yield, and low in production cost.

An exemplary embodiment of the present disclosure also provides a preparation method for a driving backplane, which may be used to prepare the driving backplane in any above-mentioned exemplary embodiment. In an exemplary implementation, the preparation method for the driving backplane may include: forming a driving structure layer on a base, wherein, the driving structure layer includes a first conductive layer and second conductive layer which are stacked; and forming a supporting structure on the driving structure layer, wherein, there is no overlapping region between an orthographic projection of the supporting structure on the base and an orthographic projection of at least one of the first conductive layer and the second conductive layer on the base.

In an exemplary implementation, forming the driving structure layer on the base may include: forming a first insulating layer and the first conductive layer arranged on the first insulating layer on the base; forming a second insulating layer and third insulating layer which cover the first conductive layer; forming the second conductive layer on the third insulating layer; forming a fourth insulating layer covering the second conductive layer; forming a fifth insulating layer on the fourth insulating layer.

In an exemplary implementation, forming the fifth insulating layer on the fourth insulating layer includes that: the fourth insulating layer is coated with a fifth insulating thin film, and the fifth insulating layer is formed by a patterning process based on a first ordinary mask. Forming the supporting structure on the driving structure layer includes that: the fifth insulating layer is coated with a supporting thin film, and the supporting structure is formed by a patterning process based on a second ordinary mask.

In an exemplary implementation, the second ordinary mask is the same as a mask for forming the first conductive layer such that a pattern of the supporting structure is complementary to that of the first conductive layer. Alternatively, the second ordinary mask is the same as a mask for forming the second conductive layer such that a pattern of the supporting structure is complementary to that of the second conductive layer.

In an exemplary implementation, the formation of the fifth insulating layer on the fourth insulating layer and the formation of the supporting structure on the driving structure layer are implemented by a patterning process based on a gray tone mask.

In an exemplary implementation, a distance between a surface of a side of the supporting structure away from the base and a surface of a side of the driving structure layer away from the base is 10 μm to 50 μm.

The contents of the preparation method for the driving backplane in the present disclosure have been introduced in detail in the above-mentioned preparation process of the driving backplane, and will not be elaborated herein.

The present disclosure further provides a display device, which includes the driving backplane of any above-mentioned exemplary embodiment.

Although the implementations of the present disclosure are disclosed above, the contents are only implementations used to easily understand the present disclosure and not intended to limit the present invention. Those skilled in the art may make any modifications and variations in implementation forms and details without departing from the spirit and scope disclosed by the present disclosure. However, the patent protection scope of the present invention should also be subject to the scope defined by the appended claims.

What we claim is:

1. A driving backplane, comprising a driving structure layer arranged on a base and a supporting structure arranged on a side of the driving structure layer away from the base, wherein the driving structure layer comprises a first conductive layer and a second conductive layer which are stacked; and there is no overlapping region between an orthographic projection of the supporting structure on the base and an orthographic projection of at least one of the first conductive layer and the second conductive layer on the base.

2. The driving backplane according to claim 1, wherein the supporting structure comprises one or more of a supporting column and a supporting dam.

3. The driving backplane according to claim 1, wherein a distance between a surface of a side of the supporting structure away from the base and a surface of the side of the driving structure layer away from the base is 10 μm to 50 μm.

4. The driving backplane according to claim 1, wherein the driving structure layer comprises a first insulating layer arranged on the base, the first conductive layer arranged on a side of the first insulating layer away from the base, a second insulating layer and a third insulating layer which cover the first conductive layer, the second conductive layer arranged on a side of the third insulating layer away from the base, a fourth insulating layer covering the second conductive layer, and a fifth insulating layer arranged on a side of the fourth insulating layer away from the base; and the supporting structure is arranged on a side of the fifth insulating layer away from the base.

5. The driving backplane according to claim 4, wherein the fifth insulating layer is made of a same material as the supporting structure.

6. The driving backplane according to claim 1, wherein a pattern of the supporting structure is complementary to that of the first conductive layer, or, a pattern of the supporting structure is complementary to that of the second conductive layer.

7. A display device, comprising a driving backplane, wherein the driving backplane comprises a driving structure layer arranged on a base and a supporting structure arranged on a side of the driving structure layer away from the base, wherein the driving structure layer comprises a first conductive layer and a second conductive layer which are stacked; and there is no overlapping region between an orthographic projection of the supporting structure on the base and an orthographic projection of at least one of the first conductive layer and the second conductive layer on the base.

8. The display device according to claim 7, wherein the supporting structure comprises one or more of a supporting column and a supporting dam.

9. The display device according to claim 7, wherein a distance between a surface of a side of the supporting structure away from the base and a surface of the side of the driving structure layer away from the base is 10 μm to 50 μm.

10. The display device according to claim 7, wherein the driving structure layer comprises a first insulating layer arranged on the base, the first conductive layer arranged on a side of the first insulating layer away from the base, a second insulating layer and a third insulating layer which cover the first conductive layer, the second conductive layer arranged on a side of the third insulating layer away from the base, a fourth insulating layer covering the second conductive layer, and a fifth insulating layer arranged on a side of the fourth insulating layer away from the base; and the supporting structure is arranged on a side of the fifth insulating layer away from the base.

11. The display device according to claim 10, wherein the fifth insulating layer is made of a same material as the supporting structure.

12. The display device according to claim 7, wherein a pattern of the supporting structure is complementary to that of the first conductive layer, or, a pattern of the supporting structure is complementary to that of the second conductive layer.

13. A preparation method for a driving backplane, comprising:
forming a driving structure layer on a base, wherein the driving structure layer comprises a first conductive layer and a second conductive layer which are stacked; and
forming a supporting structure on the driving structure layer, wherein there is no overlapping region between an orthographic projection of the supporting structure on the base and an orthographic projection of at least one of the first conductive layer and the second conductive layer on the base.

14. The preparation method according to claim 13, wherein the forming a driving structure layer on a base comprises:
forming, on the base, a first insulating layer and the first conductive layer arranged on the first insulating layer;
forming a second insulating layer and a third insulating layer which cover the first conductive layer;
forming the second conductive layer on the third insulating layer;
forming a fourth insulating layer covering the second conductive layer; and
forming a fifth insulating layer on the fourth insulating layer.

15. The preparation method according to claim 14, wherein
the forming a fifth insulating layer on the fourth insulating layer comprises: coating a fifth insulating thin film on the fourth insulating layer, and forming the fifth insulating layer by a patterning process based on a first ordinary mask; and
the forming a supporting structure on the driving structure layer comprises: coating a supporting thin film on the fifth insulating layer, and forming the supporting structure by a patterning process based on a second ordinary mask.

16. The preparation method according to claim 15, wherein the second ordinary mask is the same as a mask for forming the first conductive layer to enable a pattern of the supporting structure to be complementary to that of the first conductive layer; or, the second ordinary mask is the same as a mask for forming the second conductive layer to enable a pattern of the supporting structure to be complementary to that of the second conductive layer.

17. The preparation method according to claim 14, wherein the formation of the fifth insulating layer on the fourth insulating layer and the formation of the supporting structure on the driving structure layer are implemented by a patterning process based on a gray tone mask.

18. The preparation method according to claim 13, wherein a distance between a surface of a side of the supporting structure away from the base and a surface of a side of the driving structure layer away from the base is 10 μm to 50 μm.
